(19) United States
(12) Patent Application Publication
(10) Pub. No.: US 2006/0267121 A1
(43) Pub. Date: Nov. 30, 2006

(54) Microlenses for imaging devices

(76) Inventor: Jin Li, Boise, ID (US)

Correspondence Address: DICKSTEIN SHAPIRO LLP, 1825 EYE STREET NW, Washington, DC, 20006-5403, US

(21) Appl. No.: 11/497,365

(22) Filed: Aug. 2, 2006

Related U.S. Application Data
(62) Division of application No. 10/653,222, filed on Sep. 3, 2003.

(51) Int. Cl. H01L 27/14

(52) U.S. Cl. 257/428

(57) ABSTRACT

A microlens includes a first light conductor having at least one concave recess, and a second light conductor in the recess. The curvature of the recess and the refractive indices of the light conductors cause incident light from the area of the microlens to be transmitted to a photosensor with a smaller area. In an array of microlenses, recesses may be separated to prevent crosstalk.

### FIELD OF THE INVENTION

The present invention relates generally to microlenses, and more specifically to microlenses for use in an imaging device.

### BACKGROUND OF THE INVENTION

Imaging devices, including charge coupled devices (CCD) and complementary metal oxide semiconductor (CMOS) sensors have commonly been used in photo-imaging applications.

Exemplary CMOS imaging circuits, processing steps thereof, and detailed descriptions of the functions of various CMOS elements of an imaging circuit are described, for example, in U.S. Pat. No. 6,140,630 to Rhodes, U.S. Pat. No. 6,376,868 to Rhodes, U.S. Pat. No. 6,310,366 to Rhodes et al., U.S. Pat. No. 6,326,652 to Rhodes, U.S. Pat. No. 6,204,524 to Rhodes, and U.S. Pat. No. 6,333,205 to Rhodes. The disclosures of each of the forgoing patents are hereby incorporated by reference in their entirety.

A conventional method of generating a color image signal using a CMOS imager is depicted in FIG. 1. Light from a subject being imaged is incident as light radiation 1000 and passes through a set of conventional microlenses 12a, 12b, 12c formed on a planarization layer 10. After passing through the planarization layer 10, the light radiation 1000 is filtered by color filters 22a, 22b, 22c, which together form a color filter array 23. Each color filter 22a, 22b, 22c in the array 23 allows predominantly light of a respective specific color to pass through the array 23. A color is defined to be light having a specific range of wavelengths. Typical color filters 22a, 22b, 22c include red, green, and blue filters (RGB), or cyan, magenta, and yellow (CMY) filters. A typical array 23 includes thousands or millions of filters 22a, 22b, 22c arranged in an appropriate pattern.

Each microlens 12a, 12b, 12c and color filter 22a, 22b, 22c combination corresponds to a respective photosensor 24a, 24b, 24c, the microlenses 12a, 12b, 12c, color filter 22a, 22b, 22c, photosensor 24a, 24b, 24c, and associated readout circuitry forming respective pixel cells 26a, 26b, 26c. Each photosensor 24a, 24b, 24c is a light sensitive device that converts light striking the photosensor 24a, 24b, 24c into free charge carriers that can, in turn, be used to produce an electrical signal, such as a voltage level. Each pixel cell's signal is read out and converted to a digital signal. A processor receives digital signals representing light 1000 sensed by photosensors over an entire array and provides output signals defining a digital color image.

Use of microlenses significantly improves the photosensitivity of the imaging device by collecting light from a large light collecting area and focusing it onto a small photosensitive region, e.g., photosensors 24a, 24b, 24c of pixel cells 26a, 26b, 26c. The ratio of the light collecting area in the photosensitive region to the total area of the pixel cell is defined as a fill factor.

Conventional lens technology for digital imaging devices uses a microlens with a polymer coating that is patterned into square or circular microlenses, each over a respective photosensitive region. These microlenses are shaped and cured during manufacturing. Conventional methods of fabricating microlenses include a step of baking a microlens precursor. The conventional microlens initially has a block shape, and, when baked, the melted portions of the microlens flow and form a desired curved shape. This method is complex, and may result in inconsistent spherical shapes.

Additionally, as the size of imager arrays and photosensitive regions of a pixel cells decrease, it is becoming increasingly difficult to manufacture microlenses for the increasingly smaller photosensitive regions. One reason for this is increased difficulty of constructing a smaller lens that is optimally adjusted for absorption, refraction, diffraction, and/or other chromatic effects that occur as light passes through the microlens and other regions. Also, it is becoming increasingly difficult to correct for distortion created by multiple regions, e.g. metallization and insulating layers, above the photosensitive region in a pixel cell, resulting in increased crosstalk between adjacent pixels. “Crosstalk” results when off-axis light strikes a microlens at an obtuse angle of incidence. The off-axis light misses the intended photosensor, and instead strikes an adjacent photosensor.

Consequently, smaller imagers with untuned or non-optimized microlenses may suffer from poor optimal color fidelity, signal-to-noise ratios, and may not be able to operate over a wide range of lighting conditions.

### BRIEF SUMMARY OF THE INVENTION

The present invention seeks to improve the light transmission characteristics of microlenses and methods of microlens formation. Exemplary embodiments provide, in both method and apparatus aspects, microlenses in which a first light conductor has at least one concave recess, and a second light conductor is in the recess.

### BRIEF DESCRIPTION OF THE DRAWINGS

The above-described features and advantages of the invention will be more clearly understood from the following detailed description, which is provided with reference to the accompanying drawings in which:

FIG. 1 illustrates a portion of a conventional imaging device;

FIG. 2 illustrates a cutaway perspective view of a microlens according to an exemplary embodiment of the invention;

FIG. 3 illustrates a cutaway perspective view of a microlens according to another exemplary embodiment of the invention;

FIG. 4 is a cross-sectional view of an imaging device with an array of microlenses as in FIG. 2;

FIG. 5 is a cross-sectional view of an imaging device with an array of microlenses as in FIG. 3;

FIGS. 6-8 illustrate stages in fabrication of an imaging device as in FIG. 4;

FIG. 9 illustrates a further stage following the stage in FIG. 8, resulting in an imaging device as in FIG. 5;

FIGS. 10-11 illustrate an imaging device according to another exemplary embodiment of the invention;

FIG. 12 is a block diagram of a CMOS imager with an array of microlenses in accordance with an exemplary embodiment of the invention; and

FIG. 13 is a schematic diagram of a processor system with a CMOS imager as in FIG. 12.

### DETAILED DESCRIPTION OF THE INVENTION

In the following detailed description, reference is made to the accompanying drawings which form a part hereof, and in which is shown, by way of illustration, specific embodiments in which the invention may be practiced. These embodiments are described in sufficient detail to enable those skilled in the art to practice the invention, and it is to be understood that other embodiments may be utilized, and that structural, logical, and electrical changes may be made without departing from the spirit and scope of the present invention.

The term “substrate” is to be understood to include any semiconductor-based structure that has an exposed semiconductor surface. The semiconductor structure should be understood to include silicon, silicon-on-insulator (SOI), silicon-on-sapphire (SOS), doped and undoped semiconductors, epitaxial layers of silicon supported by a base semiconductor foundation, and other semiconductor structures. The semiconductor need not be silicon-based. The semiconductor could be silicon-germanium, germanium, or gallium arsenide. When reference is made to the substrate in the following description, previous process steps may have been utilized to form regions or junctions in or over the base semiconductor or foundation.

The term “pixel cell” refers to a picture element unit cell containing a photosensor and other components for converting electromagnetic radiation to an electrical signal. For purposes of illustration, a representative CMOS imager pixel cell is illustrated in the figures and description herein. However, this is just one example of the types of imagers and pixel cells with which the invention may be used.

The term “light conductor” refers to any material through which light radiation can pass, reflect, or refract. Materials that could form a light conductor include, but are not limited to, glass, for example, zinc selenide (ZnSe), boro-phospho-silicate glass (BPSG), phosphosilicate glass (PSG), borosilicate glass (BSG), silicon oxide, silicon nitride, or silicon oxynitride; an optical thermoplastic material such as tantalum pentoxide (Ta₂O₅), titanium oxide (TiO₂), polymethylmethacrylate, polycarbonate, polyolefin, cellulose acetate butyrate, or polystyrene; a polyimide; a thermoset resin such as an epoxy resin; a photosensitive gelatin; or a radiation curable resin such as acrylate, methacrylate, urethane acrylate, epoxy acrylate, or polyester acrylate. The preceding materials are only illustrative examples.

The term “microlens” refers herein to one of an array of optical components over an array of photosensors; each microlens tends to focus incident light toward a respective photosensor. A microlens array may be part of a layered structure formed on a substrate using photolithographic techniques.

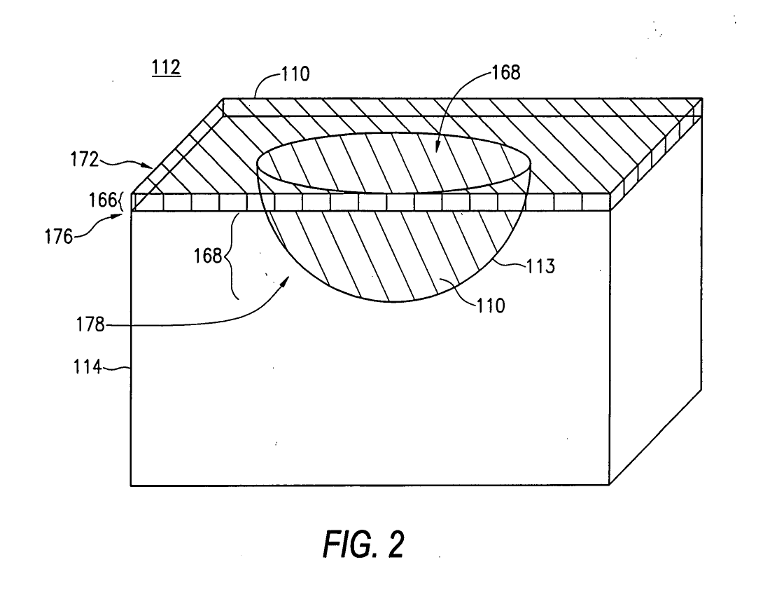

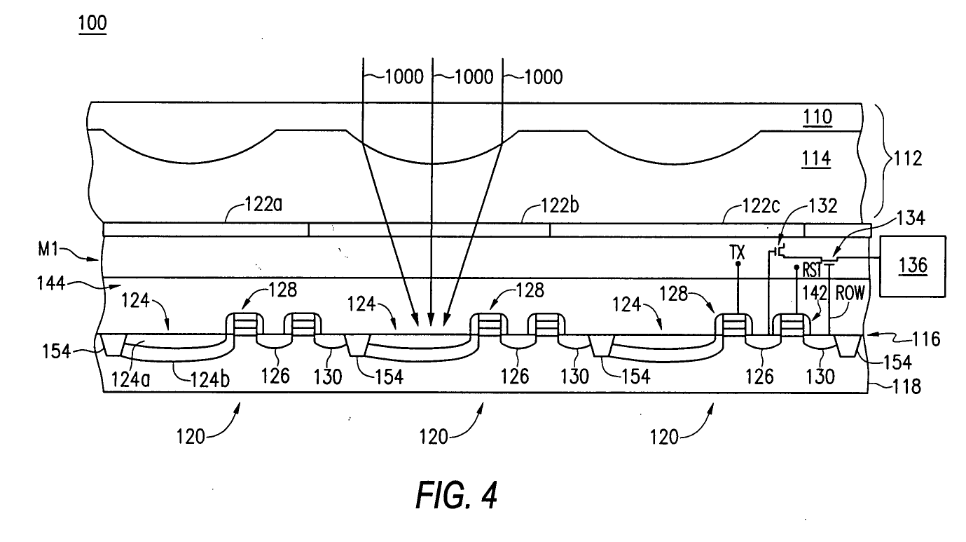

Referring now to the drawings, where like elements are designated by like reference numerals, an exemplary embodiment of the invention is depicted in FIG. 2. An illustrated microlens 112 has two light conductors: a first light conductor 114 having a planar surface 176 in which is formed at least one concave recess 178; and a second light conductor 110 formed over the first light conductor 114 and within the recess 178. In this example, the illustrated microlens 112 has a planar surface 172. The second light conductor 110 has a peripheral portion 166 and a middle portion 168. The peripheral portion 166 is formed over the planar surface 176 of the first light conductor 114, and has a thickness approximately equal to:

$$\frac{λ}{2 * N} , \qquad ( 1 )$$

wherein λ refers to a wavelength, and N refers to the index of refraction (discussed further below). The thickness of the peripheral portion 166 of the second light conductor 110 reduces crosstalk between the pixel cells 120 (FIG. 4) by spectral reflectance.

Peripheral portion 166 could alternatively be an opaque layer, different than middle portion 168. For example, peripheral portion 166 could be poly-silicon. The opaque nature of peripheral portion 166 decreases crosstalk between adjacent pixel cells. The middle portion 168 of the second light conductor 110 fills the concave recess 178 of the first light conductor 114, forming a boundary 113, which serves to refract light radiation to a photosensor 124 (FIG. 4), discussed in more detail below.

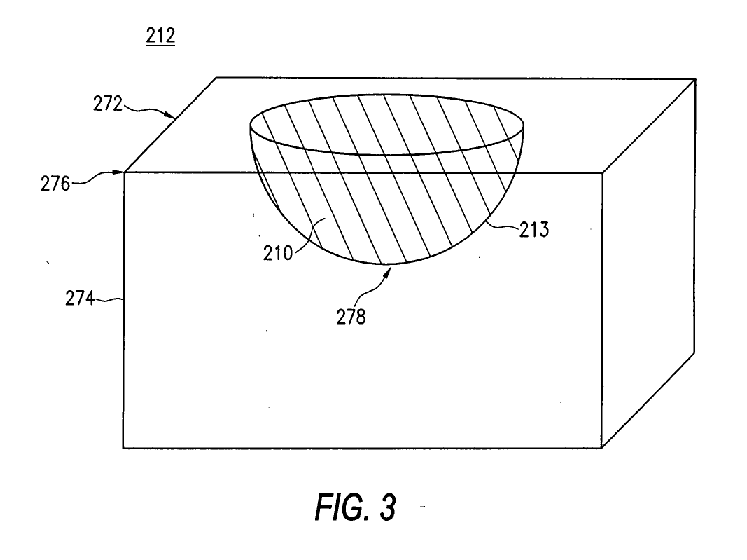

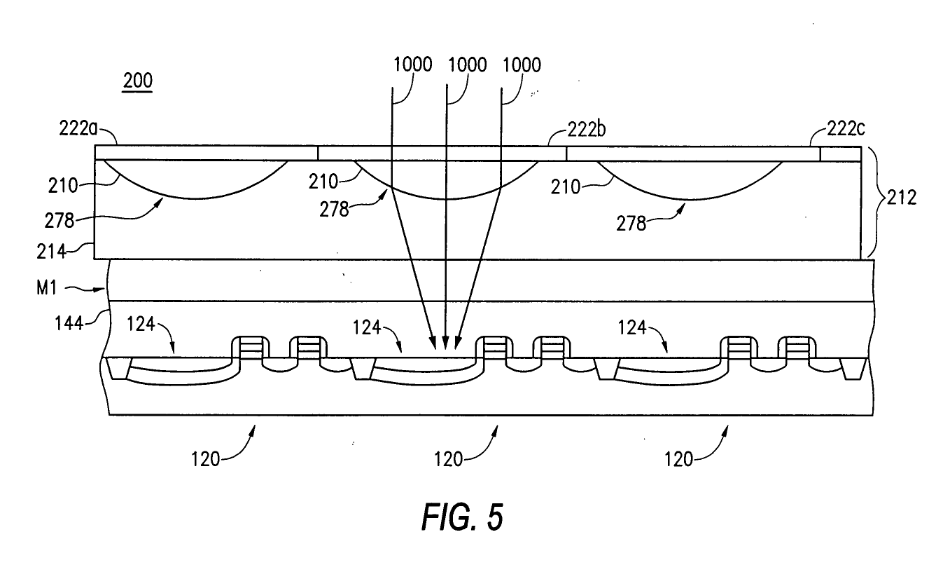

In a second exemplary embodiment shown in FIG. 3, a second light conductor 210 is formed only within a concave recess 278 of a first light conductor 214 to form a microlens 212 of an exemplary embodiment of the invention. The second light conductor 210 of this embodiment does not have a peripheral portion 166 as in FIG. 2. Instead, the topmost surface of the second light conductor 210 is in substantially the same plane as a planar surface 276 of the first light conductor 214. Because the surfaces of the first and second light conductors 214, 210 are substantially planar in the illustrated example, the formed microlens 212 also has a substantially planar surface 272 (which is substantially planar to planar surface 276 of first light conductor 214). The illustrated microlens 212 has a boundary 213 where first and second light conductors 214, 210 meet. The boundary 213 serves to refract light radiation such that the light radiation is focused towards the photosensor 124 (FIG. 5).

Referring to FIG. 2, the construction of each microlens 112 is based upon a determination of desired refractive properties at boundary 113 between the materials forming the first and second light conductors 114, 110. A desired refractive effect is produced by the shape of boundary 113 and the optical properties of the first and second light conductors 114, 110, which can be chosen to increase the fill factor of the associated pixel cell. The same is true for microlens 212 illustrated in FIG. 3.

Refraction is the bending of the path of a light wave as it passes across a boundary (e.g., boundary 113, 213) separating two mediums. Refraction is described in Snell's Law as:
N₁*sin θ₁=N₂*sin θ₂.
The angle at which an incident light wave encounters a boundary is referred to as the angle of incidence (θ₁). The angle at which a refracted light wave moves in relation to the boundary is referred to as the angle of refraction (θ₂). N₁ and N₂ refer to the indices of refraction associated with the two materials that form a boundary. As is known to those skilled in the art, refraction is caused by the difference in speed of light in the two materials.

In the embodiments depicted in FIGS. 2 and 3, the microlenses 112, 212 include two different light conductors 110, 114, and 210, 214, respectively, selected to have refractive indices that, in accordance with Snell's Law, direct more light radiation onto a photosensor 124 (FIGS. 4-5) than would otherwise occur using conventional microlens structures.

Imaging device 100 in FIG. 4 includes microlens 112 as in FIG. 2. Imaging device 100 has an array 116 of pixel cells 120. Each of pixel cells 120 includes a photosensor 124. Photosensor 124 may be any photosensitive region including a photodiode, a photogate, or the like, and the invention is not limited to the illustrated pixel cell 120. Each pixel cell 120 may be formed in or at a surface of a substrate 118. Each pixel cell 120 is illustrated as a four-transistor (4T) pixel cell. It should be noted that this illustration is not intended to limit the invention to a particular pixel cell configuration, and the pixel cell may contain three, four, five, or more transistors, or could be implemented as a passive pixel without transistors.

The microlens 112 operates to refract incident light radiation 1000 onto the photosensor 124. Each photosensor 124 has a p+ region 124a and an n-type region 124b. When incident light contacts the illustrated photosensor 124, electrons accumulate in the n-type region 124b. The electrons are then transferred to a charge collection region (or floating diffusion region) 126 when the transfer gate 128 is activated by a TX signal. When row select transistor 134 is turned on by the ROW signal, source follower transistor 132 controls a signal provided to readout circuitry 136 to indicate quantity of charge in region 126. Reset gate 142 can be activated by signal RST to reset region 126 for another readout operation or for dual sampling. It should be noted that the source follower transistor 132, row select transistor 134, and readout circuitry 136 are omitted from subsequent drawings for the sake of clarity.

The imaging device 100 may include additional layers. For example, additional processing methods may be used to form insulating, shielding, and metallization layers to connect gate lines and other connections to the pixel sensor cells. Also, an additional passivation layer 144 can be formed underneath the metallization layers. The passivation layer 144 could be formed of, for example, silicon dioxide, borosilicate glass (BSG), phosphosilicate glass (PSG), or boro-phospho-silicate glass (BPSG), which is CMP planarized and etched to provide contact holes. These contact holes are then metallized to provide contacts. Conventional layers of conductors and insulators may also be used to interconnect the structures and to connect the pixel to peripheral circuitry. For the sake of clarity, these layers will collectively be referred to as an M1 layer.

In the operation of the invention, light radiation 1000 passes through the microlens 112, which acts to condense and focus the light radiation 1000 onto the photosensor 124, due to the concave shape of the microlens 112, and the desired properties of the materials forming first and second light conductors 110, 114 in accordance with Formula (1) discussed above with respect to FIGS. 2 and 3. Although FIG. 4 and subsequent figures depict the light radiation 1000 as being generally perpendicular to the pixel cell substrate 118, it may actually be incident at other angles and is focused or concentrated onto the photosensor 124. After penetrating the microlens 112, the light radiation 1000 is filtered through one of three colored filters (e.g., 122a, 122b, 122c). The color filters 122a, 122b, 122c are formed between the M1 layer and the first light conductor 114.

In one embodiment, the microlens 112 is formed such that the focal point of each lens is centered over each respective photosensor 124 in the array. More generally, however, the invention can be implemented with microlenses that have focal points on, above, or below the respective photosensors; that have focal points that are centered or off-centered relative to the respective photosensors; or that have poorly defined focal points, due to irregularities of defects, for example.

In this example, color filters 122a, 122b, 122c are formed between the substrate 118 and the first light conductor 114. It should be noted that the color filters 122a, 122b, 122c could also be a fluorescent material film or other device for converting the wavelength of incident light. It should also be noted that since photons of different wavelengths penetrate silicon to different depths, an alternative to the use of color filters 122a, 122b, 122c involves varying the depth of each photosensor 124. Furthermore, the invention is also applicable to a monochrome or grey-scale sensing array that does not include an array of different colored filters.

Imaging device 200 in FIG. 5 includes microlens 212, in which a first light conductor 214 has a concave recess 278, and a second light conductor 210 is formed within the concave recess 278, as described above with respect to FIG. 3. The second light conductor 210 does not have a peripheral portion 166 (FIG. 2) because the second light conductor is formed only within the concave recess 278. In this embodiment, color filters 222a, 222b, 222c are formed over the second light conductor 210.

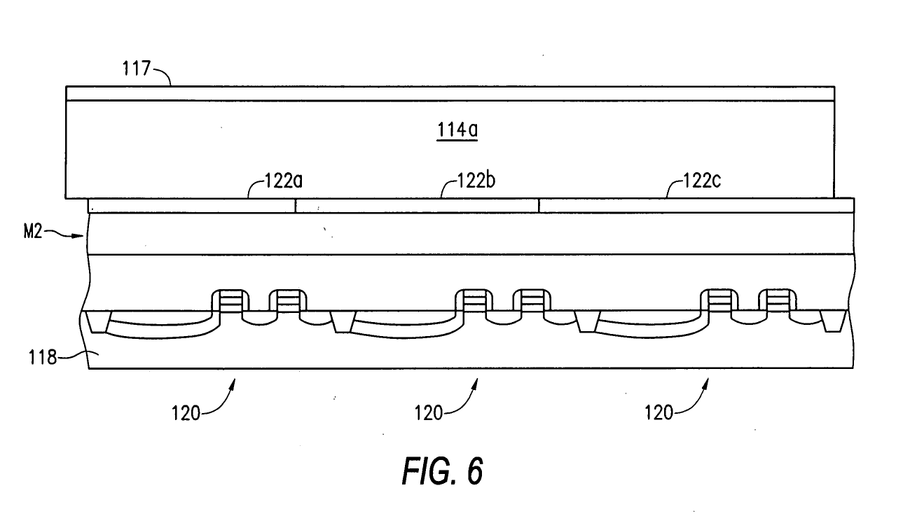

FIGS. 6-8 illustrate stages of fabrication of an imaging device 100 as in FIG. 4. FIG. 6 illustrates a substrate 118 having pixel cells 120, peripheral circuits (not shown), contacts (not shown), and wiring (not shown) formed thereon by well known methods is. For the sake of clarity, the passivation layer 144, metallization layer M1, and light shield discussed above with respect to FIG. 4 are simply referred to as an M2 layer. Filters 122a, 122b, 122c are over the M2 layer. A precursor layer 114a of the first light conductor 114 (FIG. 4) is deposited over the color filters 122a, 122b, 122c. The precursor 114a is formed by depositing any suitable transparent material, including, but not limited to glass, for example, BPSG, PSG, BSG, silicon oxide, silicon nitride, or silicon oxynitride; an optical thermoplastic material such as polymethylmethacrylate, polycarbonate, polyolefin, cellulose acetate butyrate, or polystyrene; a polyimide; a thermoset resin such as an epoxy resin; a photosensitive gelatin; or a radiation curable resin such as acrylate, methacrylate, urethane acrylate, epoxy acrylate, or polyester acrylate. After precursor 114a has been deposited, it can be planarized to provide a planar surface.

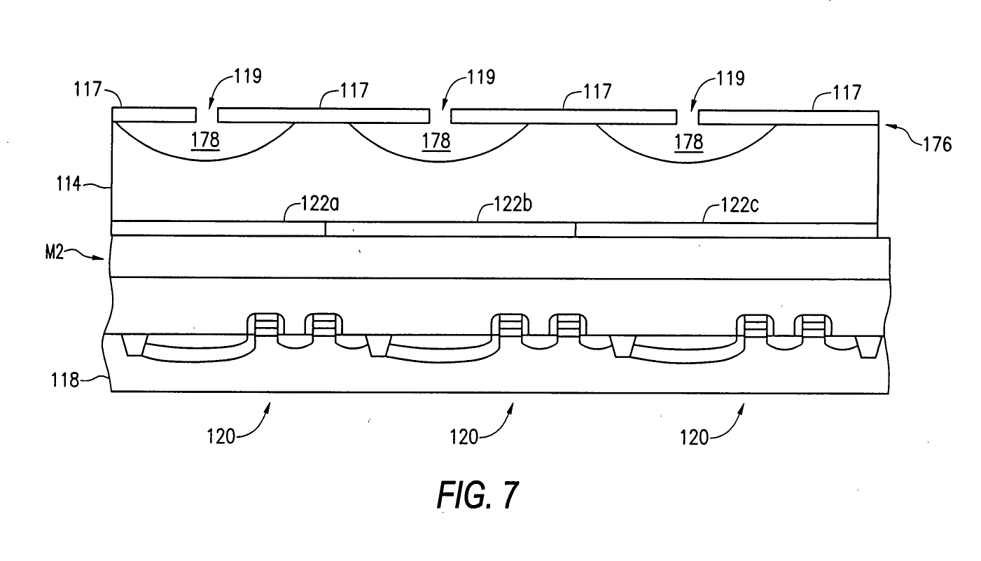

A photoresist layer 117 is deposited the precursor 114a. FIG. 7 shows the photoresist 117 patterned to create an opening 119 over each photosensor. FIG. 7 also shows that precursor 114a has been etched though each opening 119 to create a concave recess 178. In non-etched areas, precursor 114a has a planar surface 176. The concave recess 178 can be etched by chemical etching, reactive ion etching (RIE), or other means of creating a recess in precursor 114a. The shape of recess 178 can be determined by appropriate choice of the material in precursor layer 114a, the size of opening 119, the etchant, and other parameters of etching. As mentioned above, the shape of recess 178 together with the refraction at the boundary of recess 178 combine to concentrate incident light on the photosensor 124. The process of forming concave recesses 178 produces first light conductor 114 from precursor 114a.

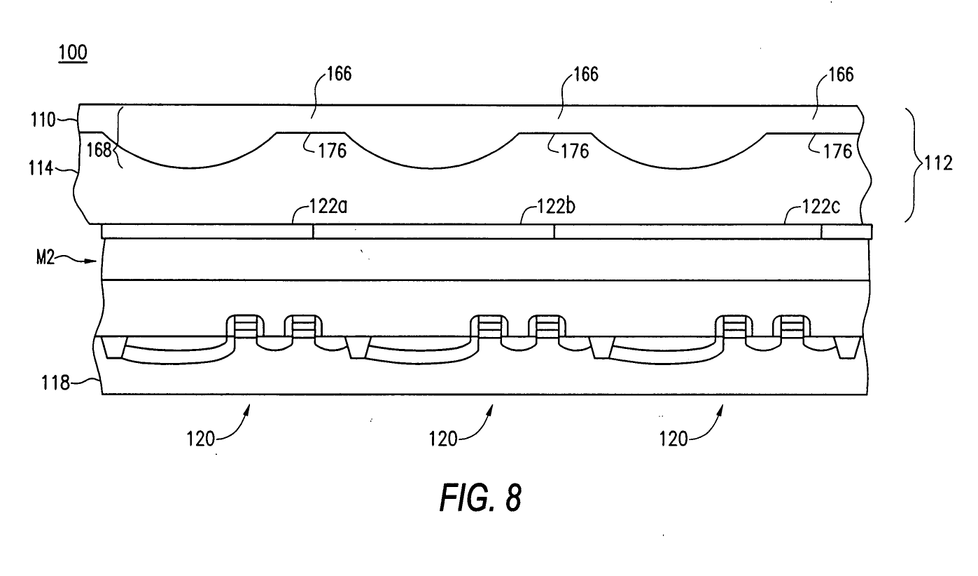

FIG. 8 illustrates a stage in which the photoresist 117 has been removed, and second light conductor 110 has been deposited over first light conductor 114, forming peripheral portion 166 over the planar surface 176 of the first light conductor 114, and forming middle portion 168 in concave recess 178 of the first light conductor 114. The second light conductor 110 is formed by depositing any suitable transparent material including, but not limited to glass, for example, zinc selenide (ZnSe), silicon oxide, silicon nitride, or silicon oxynitride, silicon-carbon (SiC) (BLOk); an optical thermoplastic material such as tantalum pentoxide (Ta₂O₅), titanium oxide (TiO₂), polymethylmethacrylate, polycarbonate, polyolefin, cellulose acetate butyrate, or polystyrene; a polyimide; a thermoset resin such as an epoxy resin; a photosensitive gelatin; or a radiation curable resin such as acrylate, methacrylate, urethane acrylate, epoxy acrylate, or polyester acrylate.

The first and second light conductors 114, 110 should be chosen from the above materials such that second light conductor 110 has a refractive index that is higher than the refractive index of the first light conductor 114, i.e., N₁₁₀>N₁₁₄. In accordance with formula (2), θ₁ increases in magnitude with distance from the center of recess 178; θ₂ similarly increases. The greater the ration of the refractive indices of the two materials that form the first light conductor 114 and the second light conductor 110, the greater the change from θ₁ to θ₂. A focusing effect can therefore be obtained if the curvature of recess 178 and the ratio of refractive indices are appropriately chosen.

Once formed, the second light conductor 110 is planarized. The second light conductor 110 can be planarized through mechanical action, such as chemical-mechanical polishing, although the step of planarization is not limited to such techniques. The thickness of the peripheral portion 166 of the second light conductor 110 is preferably determined in accordance with formula (1) discussed above with respect to FIG. 2, in order to decrease crosstalk between pixel cells 120. At this point, the microlens 112 is complete. However, additional processing can be performed. For example, desired color filters 122a, 122b, 122c may be formed over the second light conductor 110. In the illustrated embodiment, however, color filters 122a, 122b, 122c are formed between the M1 layer and the first light conductor 114, so as not to disrupt the thickness of the peripheral portion 166 of the second light conductor 110.

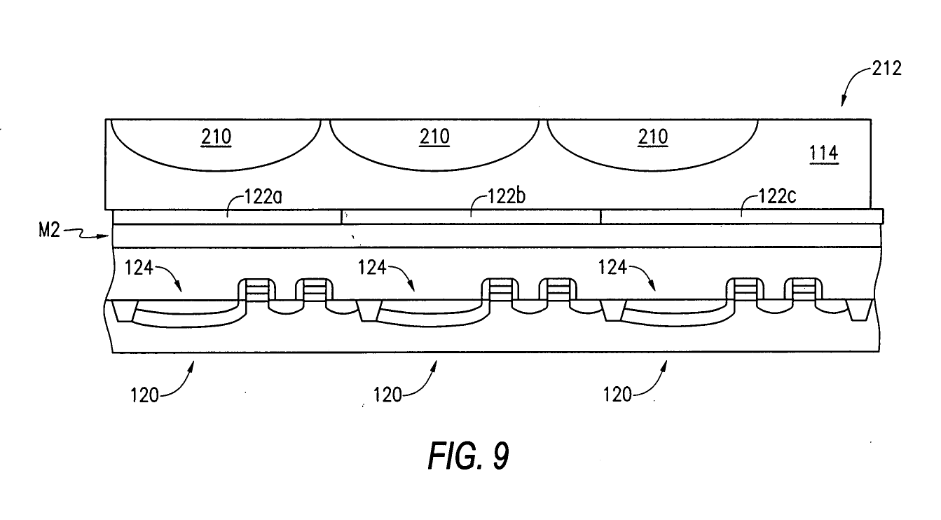

FIG. 9 illustrates how further planarization of the second light conductor 110 in FIG. 8 removes peripheral portions 166, leaving a part of middle portion 168 within the concave recess 178 (FIG. 7), forming an example of second light conductor 210 and microlens 212 as in FIGS. 3 and 5. It should be noted that color filters 222a, 222b, 222c can be formed over microlens 112 to produce the embodiment illustrated in FIG. 5.

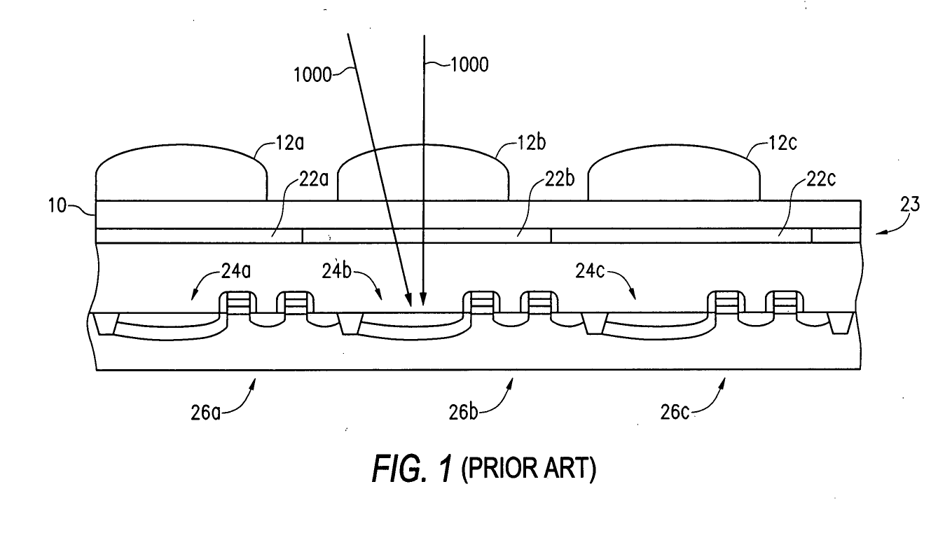

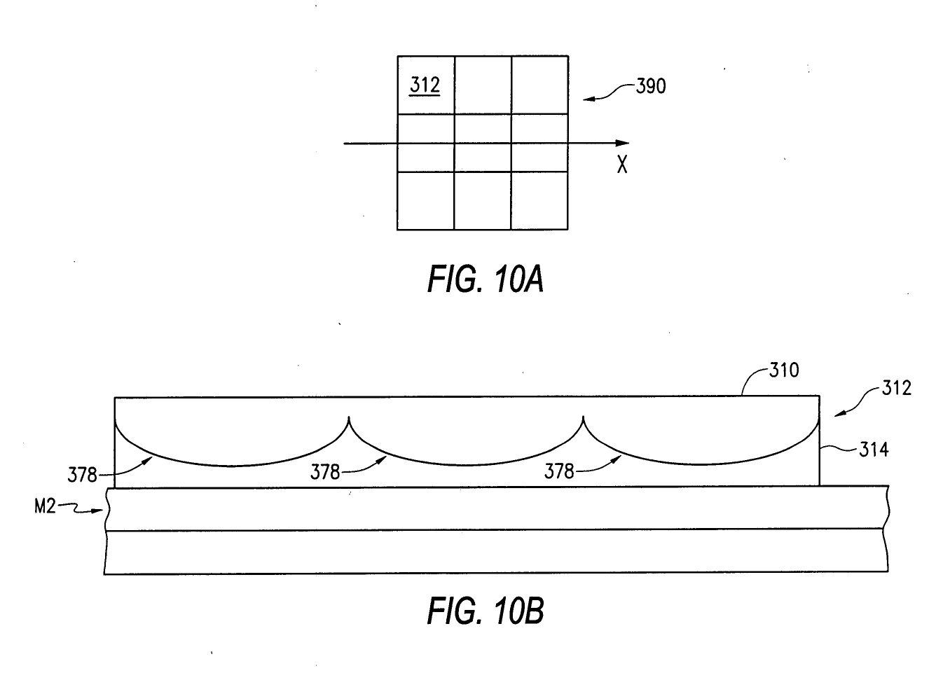

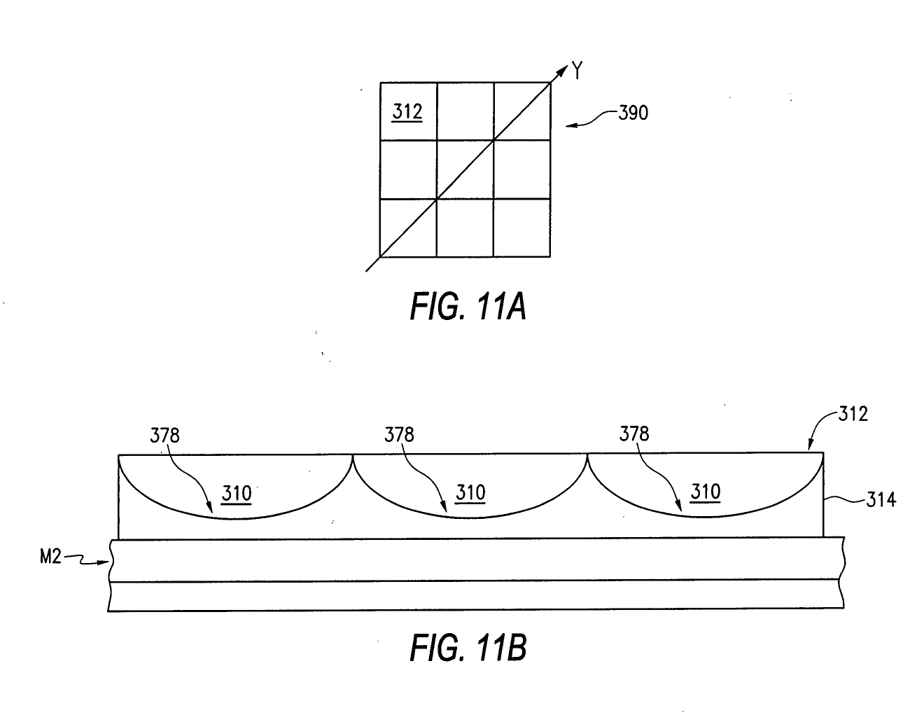

FIGS. 10-11 illustrate another exemplary embodiment of the present invention. Specifically, FIG. 10A illustrates a top-down view of a microlens array 390 comprising of a plurality of microlenses 312. In actuality, the microlens array 390 has hundreds thousands of microlenses 312 in each dimension, but is shown with only 9 microlenses for the sake of clarity. FIG. 10B illustrates a cross-sectional view of microlens array 390 taken along the X plane of FIG. 10A. FIG. 10B illustrates first light conductor 314 having recesses 378, and second light conductor 310 formed therein. The methods of forming recesses 378 and second light conductors 310 is similar to that discussed above with respect to FIGS. 6-8. The illustrated microlens is formed by etching recesses 378 deeper into the first light conductor 314, until diagonally adjacent recesses meet. The photoresist 117 (FIG. 7) is removed; and the second light conductor material 310 is formed by filling the recesses 378. The second light conductor can subsequently be planarized to form the illustrated microlens 312. The illustrated example, however, does not have a planar surface 176, 276 as described in FIGS. 2-3. Instead, each second light conductor 310 of microlens 312 is coextensive with an adjacent second light conductor 310 of an adjacent microlens 312 on the X plane of FIG. 1A. This arrangement allows for greater light to be focused towards the photosensor 124 (e.g., FIG. 9).

FIG. 11A illustrates the microlens array 390 of FIG. 10A. FIG. 11B, however, illustrates a cross-sectional view of microlens array 390 taken along the Y plane in FIG. 11A. Second light conductor 310 is not coextensive with diagonally adjacent second light conductor 310. The microlenses 312 of FIGS. 10-11 have a square shape from a top-down view. This allows virtually all light to be received by the microlens array 390, and focused onto respective photosensors 124 (e.g., FIG. 9) of respective pixels 120 (FIG. 9). Although shown as being formed on an M2 layer, microlenses 312 of FIGS. 10-11 are typically formed over respective pixel arrays 116 (FIG. 4). It should also be noted that the microlenses 312 of FIGS. 10-11 can be formed to be centered over respective photosensors 124 as discussed above with respect to FIG. 4.

Embodiments of the present invention offer advantages over previous imaging technology, including, but not limited to, eliminating the need to use a ceramic package or lid attach in forming the imager. Lenses, as in FIGS. 2-3 are not damaged during the die attach, backgrind, and mounting processes. Little or no crosstalk occurs between photodiodes in arrays as in FIGS. 4, 5, and 8-11. Additionally, the planar surfaces (e.g., 172, 272) of the microlenses (e.g., 112, 212) reduce damage that may occur during the handling of the imager device.

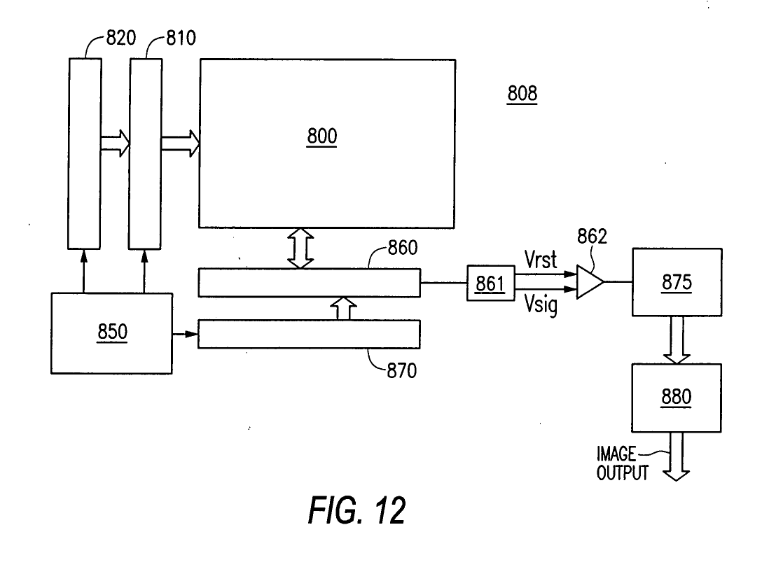

FIG. 12 illustrates a block diagram of a CMOS imager device 808 having a pixel array 800 containing a plurality of pixels arranged in rows and columns. The illustrated pixel array 800 contains at least one microlens, e.g. microlens 112, 212, 312, and 412 (FIGS. 2-11), or a combination thereof, formed over a pixel cell constructed in accordance with an exemplary embodiment of the present invention. The pixels of each row in array 800 are all turned on at the same time by a row select line, and the pixels of each column are selectively output by respective column select lines. The row lines are selectively activated by a row driver 810 in response to row address decoder 820. The column select lines are selectively activated by a column selector 860 in response to column address decoder 870. The pixel array is operated by the timing and control circuit 850, which controls address decoders 820, 870 for selecting the appropriate row and column lines for pixel signal readout. The pixel column signals, which typically include a pixel reset signal (Vᵣₛₜ) and a pixel image signal (V_{sig}), are read by a sample and hold circuit 861 associated with the column selector 860. A differential signal (Vᵣₛₜ−V_{sig}) is produced by differential amplifier 862 for each pixel, and the differential signal is amplified and digitized by analog to digital converter 875 (ADC). The analog to digital converter 875 supplies the digitized pixel signals to an image processor 880 which can perform image processing before providing image output signals.

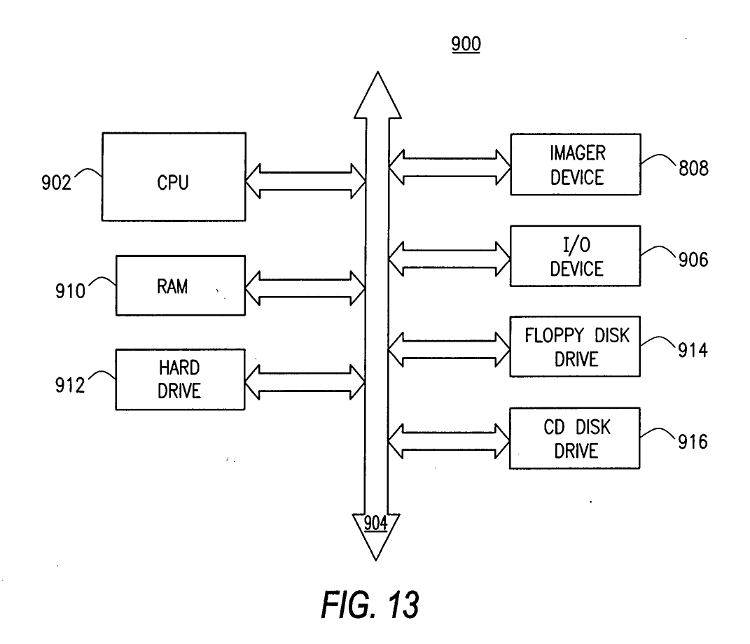

FIG. 13 shows system 400, a typical processor based system modified to include an imager device 808 as in FIG. 12. Processor based systems exemplify systems of digital circuits that could include an imager device 808. Examples of processor based systems include, without limitation, computer systems, camera systems, scanners, machine vision systems, vehicle navigation systems, video telephones, surveillance systems, auto focus systems, star tracker systems, motion detection systems, image stabilization systems, and data compression systems for high-definition television, any of which could utilize the invention.

System 900 includes an imager device 808 having the overall configuration depicted in FIG. 12 with pixels of array 800 constructed in accordance with any of the various embodiments of the invention. System 900 includes a processor 902 having a central processing unit (CPU) that communicates with various devices over a bus 904. Some of the devices connected to the bus 904 provide communication into and out of the system 900; an input/output (I/O) device 906 and imager device 808 are examples of such communication devices. Other devices connected to the bus 904 provide memory, illustratively including a random access memory (RAM) 910, hard drive 912, and one or more peripheral memory devices such as a floppy disk drive 914 and compact disk (CD) drive 916. The imager device 808 may receive control or other data from CPU 902 or other components of system 900. The imager device 808 may, in turn, provide signals defining images to processor 902 for image processing, or other image handling operations.

It should again be noted that although the invention has been described with specific references to imaging devices, i.e. CMOS imagers, comprising a microlens structures for transmitting light to photosensors, the invention has broader applicability and may be used in any imaging apparatus. For example, the present invention may be used in conjunction with charge coupled device (CCD) imagers. Similarly, the processes described above are only a few methods of many that may be used. The above description and drawings illustrate embodiments which achieve the objects, features, and advantages of the present invention. Although certain advantages and embodiments have been described above, those skilled in the art will recognize that substitutions, additions, deletions, modifications and/or other changes may be made without departing from the spirit or scope of the invention. Accordingly, the invention is not limited by the foregoing description but is only limited by the scope of the appended claims.

1-32. (canceled)

33. A method of forming an imaging device, said method comprising:
providing a substrate having a plurality of photosensitive regions; and
forming an array of microlenses, the array including a respective microlens over each of said plurality of photosensitive regions by:
depositing a first light conductor precursor,
etching said first light conductor precursor to create a first light conductor having concave recesses over each of said photosensitive regions such that each concave recess contacts an adjacent concave recess; and
forming a second light conductor within each concave recess such that said second light conductor is coextensive with an adjacent second light conductor.

34-35. (canceled)

36. The method of claim 33, further comprising the act of forming a color filter between said substrate and said second light conductor.

37. The method of claim 33, wherein each first light conductor has a first index of refraction and each second light conductor has a second index of refraction that is different from said first index of refraction.

38. The method of claim 33, wherein at least one of said first light conductors is formed of a material selected from the group consisting of glass, an optical thermoplastic material, a polyimide, a thermoset resin, a photosensitive gelatin, and a radiation curable resin.

39. The method of claim 33, wherein at least one of said second light conductors is formed of a material selected from the group consisting of glass, an optical thermoplastic material, a polyimide, a thermoset resin, a photosensitive gelatin, and a radiation curable resin.

40. (canceled)

41. The method of claim 33, wherein said array of concave recesses is formed by reactive ion etching said first light conductor.

42-46. (canceled)
